(19) United States
(12) Patent Application Publication
(10) Pub. No.: US 2013/0063184 A1
(43) Pub. Date: Mar. 14, 2013

(54) HIGH TEMPERATURE OPERATION SILICON CARBIDE GATE DRIVER

(71) Applicants: Xiaoning Liang, Santa Ana, CA (US); Chunhu Tan, Irvine, CA (US); Zhigang Lin, Irvine, CA (US)

(72) Inventors: Xiaoning Liang, Santa Ana, CA (US); Chunhu Tan, Irvine, CA (US); Zhigang Lin, Irvine, CA (US)

(73) Assignee: AEGIS TECHNOLOGY, INC, Garden Grove, CA (US)

(21) Appl. No.: 12/878,931

(22) Filed: Sep. 9, 2010

(51) Int. Cl. H03K 3/00; H01L 27/088; H01L 29/161

(52) U.S. Cl. 327/108; 257/77; 257/E29.084

(57) ABSTRACT

Versions of the present invention have many advantages, including operation under high temperatures, or high frequencies while providing the required current for switching a SiC VJFET, providing electrical isolation and minimizing dv/dt noise. One embodiment is a silicon carbide gate driver comprising a first group of silicon on insulator devices and passive components and a second group of silicon carbide devices. The first group may have equivalent temperatures of operation and equivalent frequencies of operation as the second group.

### BACKGROUND OF THE INVENTION

(1) Field of the Invention

The present invention relates to a high-temperature capable gate driver, for driving the input gates of silicon carbide (SiC) vertical junction field effect transistors (VJFETs). The present invention may be used in the design of power electronics.

(2) Description of Related Art Including Information Disclosed Under 37 CFR 1.97 and 1.98

Gate driver circuits are a critical component in the design of power conversion systems, including both converters and inverters. A typical power converter is comprised of various components including a controller (or control signal generator), gate driver, power devices, and auxiliary circuits such as a monitoring and protective circuits. Gate drivers provide an interface between the low-power controller and power devices. Generally, the gate driver circuit consists of a power amplifier that accepts a low-power input signal from a controller or digital signal processor (DSP). Such a controller or DSP generates a pulse width modulated (PWM) signal. The gate driver circuit then converts this PWM signal into a high-power driving signal (either a high voltage or high current signal) for a targeted power device. With the gate driver, SiC VJFETs can be switched on and off and can be used for the design of various types of power conversion systems including DC to DC converters and DC to AC inverters.

Gate driver circuits may be found within power converters and inverters. Such power converters and inverters are used for various applications and in various environmental settings. Power converters can be used for on-board power, off-vehicle power, and battery power conditioning systems. Inverters can be used for motor drives, traction motors, fans, and pumps. In addition, inverters can be used for solar energy and other renewable energy applications. The power converters and inverters found within light-, medium-, and heavy-duty hybrid electric vehicles must operate under high ambient temperature conditions.

Usage of silicon carbide components provides for numerous advantages for functions such as power converters and inverters. However, current gate drivers are not able to take full advantage of features offered by SiC power devices. For example, gate drivers used to drive SiC devices may not be able to match properties such as having high temperature (HT) capability, high frequency capability, sinking and sourcing high currents, high common mode noise immunity (dv/dt noise) or maintaining voltage isolation at high temperatures.

Generally in a power converter system, the gate driver is placed physically close to the power module in order to minimize the effect of parasitic circuit elements. This is especially important in high frequency, and/or high driving current applications. Therefore, for a SiC-based power module capable of working in a high temperature environment of ˜200° C. or more, its gate driver must exhibit similar high operation temperature capability. However, currently used gate driver modules designed for Si-based systems usually use Si-based ICs and low temperature PCB-based packaging that cannot handle high temperatures, and thus not directly used to drive SiC devices in high temperature environments.

High frequency capability is an important advantage of SiC devices, with which the passive components used can be smaller in size and lighter in weight. However, the real working frequencies of SiC devices are dictated by the gate driver frequencies. Although some current gate driver modules can provide high frequencies (˜200 kHz), they do not have high temperature capability.

The ability to sink and source high current is necessary for the gate driver in high power applications, because higher current is needed to switch on/off the power devices in these cases. Many commercial gate drivers provide source and sink currents far less than 10 Amps. Therefore, for SiC devices, it is necessary to ensure that the design can operate at high currents of 10-15 Amps.

Gate drive circuits are subjected to common mode noise immunity, or dv/dt noise. When the JFET switches on, a large change in voltage in a short period of time (dv/dt) occurs across the drain-to-source of the JFET. This voltage then creates a current across the parasitic gate to drain capacitance of the JFET. This current then translates into a voltage spike across the gate-to-source (V_{GS}). It is important to minimize dv/dt noise because voltage spikes across the gate-to-source may negatively affect the switching operation of the JFET.

Additional information relevant to attempts to address these problems can be found in U.S. Pat. Nos. 4,443,719, 4,748,351, 5,019,719, 5,124,595, 5,469,098, 5,481,219, 5,550,412, 6,107,860, 6,144,193, 6,822,882, 7,236,04. However, each one of these references may least suffer from one or more disadvantages such as a lack of a disclosure of a gate driver circuit for driving the input gate of silicon carbide VJFETs, inability to operate at high temperatures (e.g. 200 deg C.), insufficient current for driving the input gate of a SiC VJFET, inability to operate under high frequencies, lack of electrical isolation between the controller or DSP and the SiC VJFET, and inability to minimize dv/dt noise.

All referenced patents, applications and literatures are incorporated herein by reference in their entirety. Furthermore, where a definition or use of a term in a reference, which is incorporated by reference herein is inconsistent or contrary to the definition of that term provided herein, the definition of that term provided herein applies and the definition of that term in the reference does not apply. The invention may seek to satisfy one or more of the above-mentioned desire. Although the present invention may obviate one or more of the above-mentioned desires, it should be understood that some aspects of the invention might not necessarily obviate them.

### BRIEF SUMMARY OF THE INVENTION

Accordingly, objects of the present invention include featuring a gate driver circuit that can operate under high temperatures and operate under high frequencies while providing the required current for switching a SiC VJFET, providing the necessary electrical isolation and minimizing dv/dt noise.

One embodiment is a silicon carbide gate driver comprising: a first group of silicon on insulator devices and passive components; and a second group of silicon carbide devices. The first group may have equivalent temperatures of operation and equivalent frequencies of operation as the second group. A signal may pass through the first group before the signal passes through the second group. The passive components may be selected from the group consisting of: resistors; capacitors; diodes; and transformers. The silicon carbide device may be selected as a junction gate field-effect transistor. The temperatures of operation may be a range from −70 degrees Celsius to 250 degrees Celsius. The frequencies of operation may be a range from 100 kilohertz to 500 kilohertz. Sink/source current ratings may range from 1 to 25 Amperes.

An embodiment of the present invention is a method of driving a gate of an output stage device comprising: a first group of silicon on insulator devices and passive components; a second group of silicon carbide devices; and passing a signal through said first group and then passing said signal through said second group. The first group may have equivalent temperatures of operation and equivalent frequencies of operation as the second group. The silicon on insulator device may be selected from the group consisting of resistors; capacitors; diodes; and transformers. The silicon carbide device may be selected as a junction gate field-effect transistor. The temperatures of operation may range from −70 degrees Celsius to 250 degrees Celsius. The frequencies of operation may range from between 100 kilohertz to 500 kilohertz. Sink/source current ratings may range from 1 to 25 Amperes.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 illustrates a circuit model of an embodiment of a SiC VJFET.

FIG. 2 illustrates a circuit model of an embodiment of a gate driver circuit.

FIG. 3 illustrates a functional diagram indicating the operation of an embodiment of a gate driver circuit.

### REFERENCE NUMERALS IN DRAWINGS

The table below lists the reference numerals employed in the figures, and identifies the element or structure designated by each numeral. It should be understood that throughout the drawings, corresponding reference numerals indicate like or corresponding parts and features

10 Gate of SiC VJFET

11 Drain of SiC VJFET

12 Parasitic Resistance, R_{G}, on Gate of SiC VJFET

13 Parasitic Capacitance, C_{GD} of SiC VJFET

14 Parasitic Resistance, R_{D}, on Drain of SiC VJFET

15 Gate to Drain Current Direction for SiC VJFET

16 Gate to Source Current Direction for SiC VJFET

17 Current Source Indicating Drain Current for SiC VJFET

18 Parasitic Capacitance, C_{GS} of SiC VJFET

19 Parasitic Capacitance, C_{DS} of SiC VJFET

20 Parasitic Resistance, R_{S} of SiC VJFET

21 Source of SiC VJFET

22 V1+ voltage on Primary of Transformer T1

23 V1− voltage on Primary of Transformer T2

24 Transformer T1

25 Transformer T2

26 Diode D1

27 n-Channel MOSFET, S1

28 Gate Resistor R2

29 Diode D2

30 Capacitor C1

31 Gate Resistor R1

32 Switching SiC VJFET, M1

33 Diode D3

34 Gate Resistor R4

35 n-Channel MOSFET S2

36 Diode D4

37 Capacitor C3

38 Gate Resistor R3

39 V2+ voltage (Gate-to-Source Voltage on SiC VJFET, M1)

40 V2− voltage (Gate-to-Source Voltage on SiC VJFET, M2)

41 Output Stage SiC VJFET, W1

42 Switching SiC JFE, M2

43 +Vcc, positive supply voltage

44 Floating Ground, GND

45 Capacitor C2

46 Capacitor C4

47 −VSS, negative supply voltage

48 Floating Ground, GND

49 Output Voltage, V_{OUT} to SiC VJFET

50 Floating Ground, GND

51 V1+, Pulse Width Modulated (PWM) Signal from DSP or Controller

52 V1−, Pulse Width Modulated (PWM) Signal from DSP or Controller

53 V2+, Voltage Waveform to Gate of SiC VJFET,

54 V2−, Voltage Waveform to Gate of SiC VJFET, M2

55 VCC, positive voltage supply

56 SiC VJFET, M1

57 SiC VJFET, M2

58 Output Voltage, V_{OUT} (to output stage SiC VJFET)

59 First Primary of Transformer T1

60 Second Primary of Transformer T1

61 First Primary of Transformer T2

62 Second Primary of Transformer T2

63 First Polarity End of First Secondary of Transformer T1

64 Second Secondary of Transformer T1

65 Second Polarity End of Second Secondary of Transformer T1

66 First Polarity End of First Secondary of Transformer T2

67 Second Secondary of Transformer T2

68 Second Polarity End of Second Secondary of Transformer T2

### DETAILED DESCRIPTION OF THE INVENTION

The invention and its various embodiments can now be better understood by turning to the following detailed description of the preferred embodiments, which are presented as illustrated examples of the invention defined in the claims. It is expressly understood that the invention as defined by the claims may be broader than the illustrated embodiments described below.

Certain embodiments have features such as a robust reliable gate driver circuit, state-of-art SiC and SOI devices, and high-temperature passive components and packaging, thus providing long-term reliability and stability. Features of certain embodiments have gate drivers that use a modular design that is highly flexible and scalable, and can be implemented with a compact gate driver board or even a future gate driver IC.

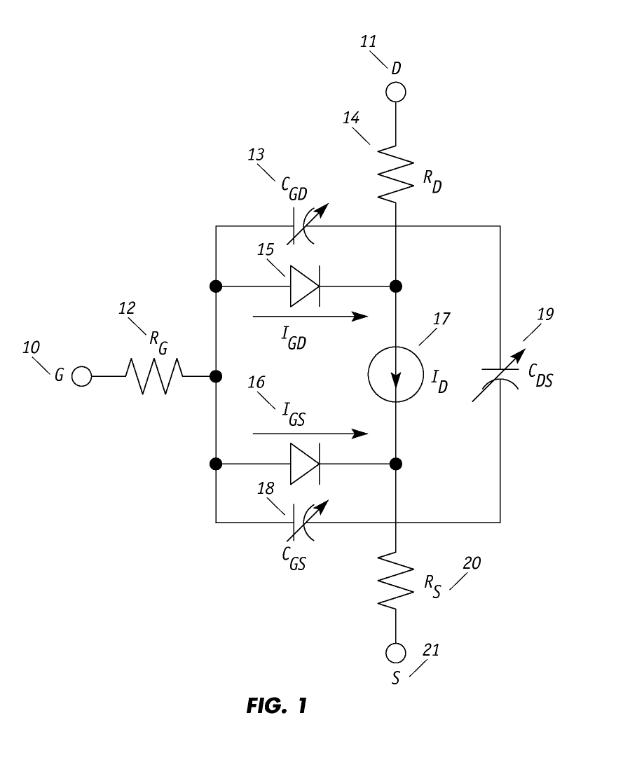

FIG. 1 illustrates an embodiment featuring a circuit model of an SiC VJFET. Here, R_{g} 12, R_{d} 14, and Rₛ 20 correspond to the parasitic resistances found in the SiC VJFET. C_{gd} 13, C_{ds} 19, and C_{gs} 18 correspond to the parasitic capacitances found in the SiC VJFET. I_{gd} 15 and I_{gs} 16 correspond to the gate to drain current and gate to source current found in the SiC VJFET. I_{d} 17 corresponds to the drain current found within the SiC VJFET. The parasitic capacitances, C_{gd} 13 and C_{gs} 18 are important to be considered during the operation of the gate driver circuit.

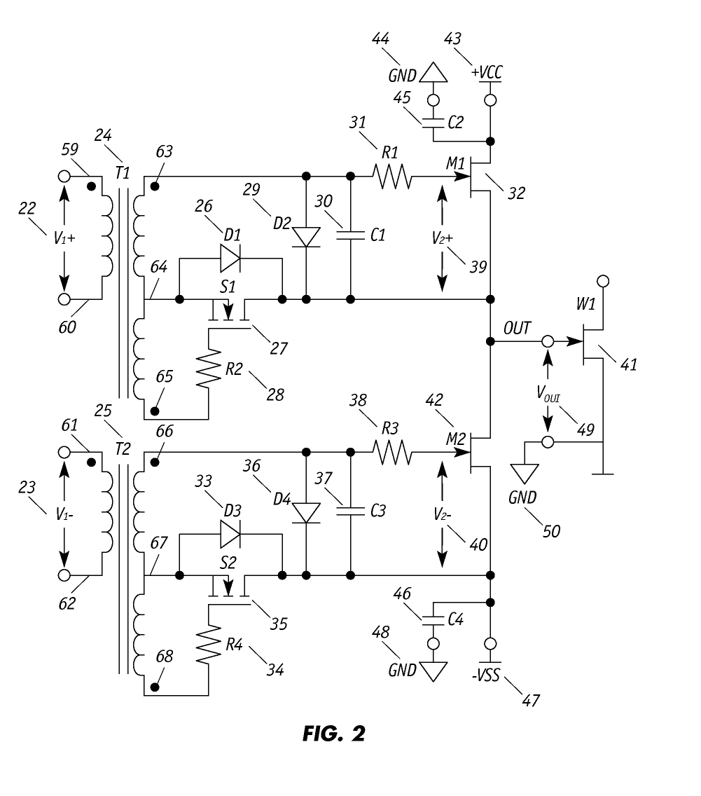

FIG. 2 illustrates an embodiment featuring a gate driver circuit. Certain embodiments featuring a gate driver are comprised of discrete components. Aspects here include a high temperature capable pulse transformer T1 24 and T2 25; high temperature capable diodes D1 26, D2 29, D3 33, D4 36; high temperature capable resistors R1 31 and R2 28; high temperature capable n-channel MOSFETs S1 27 and S2 35; high temperature capable capacitors C1 30, C2 45, C3 37, C4 46; switching SiC VJFETs M1 32 and M2 42; and an output stage SiC VJFET, W1 41. The switching SiC VJFETs, M1 32 and M2 42, are configured in a totem pole topology. The output stage SiC VJFET, W1 41 corresponds to the actual output SiC VJFET that is driven by the gate driver circuit. In addition, the gate driver circuit comprises of a positive voltage source, +Vcc 43, and negative voltage source −Vss 47. The circuit in FIG. 2 also comprises of a floating ground, designated by GND 44, 48, 50.

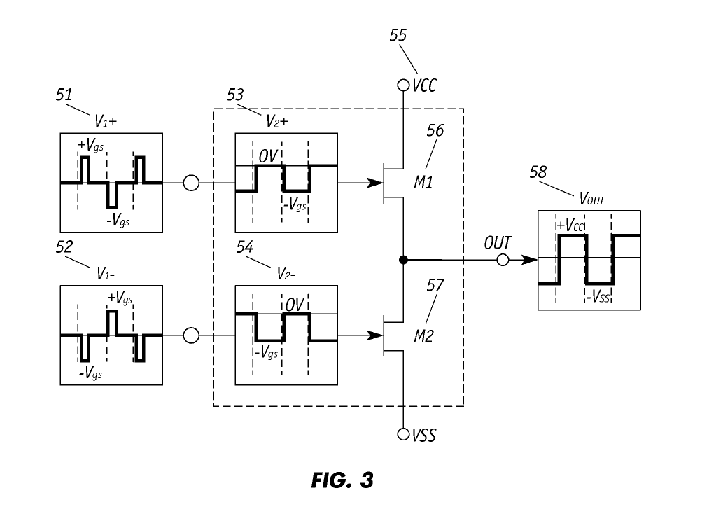

### Operation—FIG. 2 and FIG. 3

V1+ 22 and V1− 23 correspond to PWM signals from an external board, such as a DSP. Both V1+ 22 and V1− 23 are complementary PWM signals to each other. This implies that when V1+ 22 is at +Vgs voltage, V1− 23 is at −Vgs voltage. Positive voltage pulses, +Vgs present at V1+ 22 and V1+ 23 appear on the primary winding of die transformer T1 24 and T2 25. The voltage at the gates of the n-channel MOSFETs, S1 27 and S2 35, become positive, thereby switching on S1 27 and S2 35. Both C1 30 and C3 37 discharge, and 0V appears at V2+ 39 and V2− 40. When negative voltage pulses, −Vgs, appear at V1+ 22 and V1− 23, on the primary winding of transformer T1 24 and T2 25, the voltages at the gates of S1 27 and S2 35 become negative, thereby switching off S1 27 and S2 35. Both D1 26 and D3 33 conduct and C1 30 and C3 37 charge to −Vgs. A −Vgs voltage appears at V2+ 39 and V2− 40. Therefore, the voltages across V2+ 39 and V2− 40 range from 0V to −Vgs. This voltage switches on and off the switching SiC VJFETs M1 32 and M2 40, which in this embodiment are “normally-on” SiC VJFETs. When M1 32 is switched on, +Vcc voltage appears at the output, while M2 42 is switched off. When M2 42 is switched on, −Vss appears at the output, while M1 32 is switched off. The voltage at Vout 49 thereby ranges from −Vss to +Vcc. The voltage at Vout 49 is used as the gate drive voltage (V_{gs}) to drive the SiC power device W1 41.

FIG. 3 illustrates a functional diagram indicating the operation of an embodiment featuring a gate driver circuit. V1+ 51 and V1− 52 are PWM signals from an external control board, such as a DSP. Both V1+ 51 and V1− 52 are complementary PWM signals to each other. A positive voltage pulse, +Vgs present at V1+ 51 and V1− 52 will produce 0V at V2+ 53 and V2− 54. This voltage of 0V is required for switching on, the “normally-on” and switching SiC VJFETs, M1 56 and M2 57. A negative voltage pulse of −Vgs at V1+ 51 and V1− 52 will produce a −Vgs voltage at V2+ 53 and V2− 54, which is used for switching off the “normally-on” and switching SiC VJFETs, M1 56 and M2 57. M1 56 and M2 57 are configured in a “totem-pole” topology. Both M1 56 and M2 57 are components of the gate driver circuit. During the time interval when 0V appears at the gate of M1 56, a +Vcc voltage appears at the output, “OUT” 58. During the time interval, when 0V appears at the gate of M2 57, a −Vss voltage appears at the output. The output voltage, Vout 58, ranges from +Vcc to −Vss, with the desired switching frequency dictated by the frequency of the PWM signal, V1+ 51 and V1− 52. Vout 58 then can be further used as the gate drive voltage (V_{gs}) to drive the SiC power device W1 41, shown in FIG. 2.

As demonstrated in FIG. 2 and FIG. 3 as an exemplary embodiment, a novel two-stage gate drive circuit is utilized in order to increase the sink/source capability to values such as 15 A. This embodiment is comprised of both SOI and SiC devices, as shown in FIGS. 2 and 3, which is based on the edge-triggered gate drive, yet with the implementation of a normally-on SiC JFET device at the output stage. In this embodiment, a totem pole topology consisting of two of these circuits is used to produce the desired gate drive voltage by adjusting the V_{CC} and V_{SS}. Therefore this gate driver module embodiment may be a multi-use gate driver, which can be used to drive SiC MOSFET and VJFET (normally-on and normally-off) respectively, through regulating V_{CC} and V_{SS} so as to enable the voltage to match the required value for a particular kind of switch devices.

A high-temperature transformer is used to provide high VRMS isolation, as there is no optocoupler, normally used for Si-based gate driver can work at high temperature. Therefore, this embodiment may fully realize and match the potentials of SiC power devices. In addition, each discrete HT capable components can be integrated into a compact gate driver module, using the high-temperature packaging technology.

M1 is a normally-on SiC VJFET whose thread voltage is −17V. Usually this VJFET require a −25V to fully turn off. The maximum operating continues current can be up to 15 A at temperature 225° C. M1 and M2 may consist of a totem pole topology, which is generally used in conventional gate drive designs.

T1 and T2 are custom designed transformers which can handle high current and work at high temperatures and high frequencies. These transformers may be used to replace the optocouplers in conventional gate drive designs to provide high VRMS isolation, high common mode noise immunity in the course of high frequency operation.

S1 is a HT N-channel Power FET, such as a Honeywell HTNFET, which is used to discharge the C1 so that switches M1 on. Meanwhile the gate source voltage is clamped to zero through diode D2.

D1 is a SiC diode which is used to charge the C1 while S1 is off so that a negative voltage appears at the gate of M1 and switches M1 off.

Passive components include gate resistor R1 and R2, which are used to limit the instantaneous gate charge current when switching on and off. C1 is used to stable the gate voltage of M1 when it is charged and C2 is used to reduce the ripple of V_{SS} and V_{CC}.

FIG. 3 illustrates the operating principle of an embodiment. V1+ and V1− are the PWM signals from external control board. The positive pulse in V1+ and V1− will trigger the circuit and produce a 0V at V2+ and V2−, which are the gate drive voltages for normally-on SiC VJFETs M1 and M2, and turn them on. Also, the negative pulse in V1+ and V1− will produce a −Vgs at V2+ and V2−, to turn off M1 and M2. Therefore, V2+ and V2− can be controlled in a complementary manner, and the controlled M1 and M2 consist of a totem pole topology. The output voltage, Vout, will be produced with an up-level of +Vcc and down-level of −Vss, with the desired switching frequency dictated by the frequencies of V1+ and V1−. Then, Vout can be used as the gate drive voltage (VGS) to drive the SiC power device W1.

Certain embodiments disclose a high temperature gate driver module for SiC power devices, which is able to address issues such as low sink or souring current capability and limited high voltage isolation capability, while maintaining the high temperature and high frequency.

### Uses of the Invention

Embodiments of the invention may be used as a gate driver. Gate drivers are a critical component in the design of power conversion systems. A typical power converter is comprised of various components including a controller (or control signal generator), gate driver, power devices, and auxiliary circuits such as monitor and protective circuits. Gate drivers provide an interface between the low-power controller and power devices. Generally, the gate driver circuit consists of a power amplifier that accepts a low-power input signal from a controller or digital signal processor (DSP) and provides a high-power driving signal (high voltage or high current) for a targeted power device. With the gate driver, the power devices can properly function and realize the desired power conversion, such as AC-DC and DC-AC.

### Advantages of the Invention

The described versions of the present invention have many advantages, including being able to operate under high temperatures, or being able to operate under high frequencies while providing the required current for switching a SiC VJFET, and necessary electrical isolation. Other advantages may include the minimizing dv/dt noise.

Further advantages include allowing circuits to be created of a smaller size, which provides for portability and integration of electronics in tight spaces; allowing for lower on-resistance, providing for lower conduction losses and provides for higher efficiency and reduced need for thermal management (i.e. cooling hardware); allowing for higher breakdown voltages, due to higher electric breakdown fields; allowing for higher thermal conductivity, resulting in a lower junction-to-case thermal resistance and minimizes the rapid increases of device temperature in ambient temperature conditions; allowing for operation at high temperatures, resulting in smaller thermal management systems in terms of size and weight compared with Si power devices; increased reliability, which may be due to the forward and reverse characteristics of SiC devices slightly vary with temperature and time, thereby increasing reliability; being radiation-hard, where radiation does not degrade the electronic properties of SiC devices; and lastly excellent reverse recovery characteristics, implying minimal switching losses and better high-frequency performance.

An advantage such as operation under high temperature may be possible due to the selection of discrete components including both active and passive components that can withstand high temperature operation. The passive components used in the circuit include, but are not limited to, diodes, capacitors, transformers, and resistors that can withstand high temperature operation. The active components which include a n-Channel MOSFET, normally-on and normally-off SiC VJFETs can also withstand high temperature operation. A polyimide substrate (e.g. Arlon 85N) can be used as the base substrate upon which the discrete components are placed. Polyimide substrates are capable of temperature operation at up to 200 deg C.

An advantage such as providing the necessary current for charging and/or discharging the parasitic capacitances, C_{gs} and C_{gd}, allows for the switching of the SiC VJFET.

An advantage of being able to operate under high frequencies comes with a minimization of the size of passive components and to minimize the dissipation losses found within the SiC VJFET.

An advantage such as providing the necessary electrical isolation between the controller or DSP and the SiC VJFET may be achieved by selection of a transformer that minimizes any voltage noise at the input of the SiC VJFET. This prevents inadvertent switching of the SiC VJFET.

An advantage such as the minimization of dv/dt noise may be achieved by the selection of discrete components including the transformer, minimizes such noise, which prevents inadvertent switching of the SiC VJFET.

Furthermore, the invention does not require that all the advantageous features and all the advantages need to be incorporated into every embodiment of the invention. Also, this partial list of advantages is not an exhaustive list or description of all of the advantages from the embodiments and versions of the present invention.

### Closing

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed herein even when not initially claimed in such combinations.

Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility).

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Thus, specific embodiments and applications of the present invention have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Insubstantial changes from the claimed subject matter as viewed by a person with ordinary skill in the art, now known or later devised, are expressly contemplated as being equivalent within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention. In addition, where the specification and claims refer to at least one of something selected from the group consisting of A, B, C . . . and N, the text should be interpreted as requiring only one element from the group, not A plus N, or B plus N, etc.

What is claimed is:

1. A silicon carbide gate driver comprising:
a) a first group of silicon on insulator devices and passive components; and
b) a second group of silicon carbide devices.

2. The silicon carbide gate driver of claim 1, wherein:
a) said first group has equivalent temperatures of operation and equivalent frequencies of operation as said second group.

3. The silicon carbide gate driver of claim 2, wherein:
a) a signal passes through said first group and then said signal passes through said second group.

4. The silicon, carbide gate driver of claim 3, wherein said passive components are selected from the group consisting of
a) resistors;
b) capacitors;
c) diodes; and
d) transformers.

5. The silicon carbide gate driver of claim 4, wherein said silicon carbide device is selected as a junction gate field-effect transistor.

6. The silicon carbide gate driver of claim 5, wherein said temperatures of operation is a range from −70 degrees Celsius to 250 degrees Celsius.

7. The silicon carbide gate driver of claim 6, wherein said frequencies of operation is a range from 100 kilohertz to 500 kilohertz.

8. The silicon carbide gate driver of claim 7, wherein sink/source current ratings range from 1 to 25 Amperes.

9. A method of driving a gate of an output stage device comprising:
a) a first group of silicon on insulator devices and passive components;
b) a second group of silicon carbide devices; and
c) passing a signal through said first group and then passing said signal through said second group.

10. The method of claim 9, wherein
a) said first group has equivalent temperatures of operation and equivalent frequencies of operation as said second group.

11. The method of claim 10, wherein said silicon on insulator device is selected from the group consisting of
a) resistors;
b) capacitors;
c) diodes; and
d) transformers.

12. The method of claim 11, wherein said silicon carbide device is selected as a junction gate field-effect transistor.

13. The method of claim 12, wherein said temperatures of operation ranges from −70 degrees Celsius to 250 degrees Celsius.

14. The method of claim 13, wherein said frequencies of operation ranges between 100 kilohertz to 500 kilohertz.

15. The method of claim 14, wherein sink/source current ratings range from 1 to 25 Amperes.
